(19) United States
(12) Patent Application Publication
(10) Pub. No.: US 2019/0256409 A1
(43) Pub. Date: Aug. 22, 2019

(54) SURFACE GLASS WITH EMBEDDED CERAMIC PARTICLES

(71) Applicant: Apple Inc., Cupertino, CA (US)

(72) Inventors: James R. WILSON, Cupertino, CA (US); Matthew S. ROGERS, San Jose, CA (US)

(21) Appl. No.: 15/976,786

(22) Filed: May 10, 2018

Related U.S. Application Data
(60) Provisional application No. 62/632,983, filed on Feb. 20, 2018.

(51) Int. Cl. C03C 17/00; C03B 19/09; C03C 19/00; H05K 5/00; H05K 5/03

(52) U.S. Cl. CPC C03C 17/007; C03B 19/09; C03C 17/008; H05K 5/0004; H05K 5/0017; H05K 5/03; C03C 19/00

(57) ABSTRACT

Components of an electronic device, such as glass components, are susceptible to surface damage. Glass components can be strengthened by providing ceramic particles at the exposed surface of the glass. Ceramic particles can also provide optical features, such as color, opacity, and haze to enhance the appearance of the resulting composite article. Where ceramic particles are provided at the exposed surface, the ceramic particles can also produce a desired tactile feature. These features can be provided in various combinations and in different ways across different regions to produce a desired look and feel of the resulting composite article.

### CROSS-REFERENCE TO RELATED APPLICATIONS

This application claims the benefit of U.S. Provisional Application No. 62/632,983, entitled “SURFACE GLASS WITH EMBEDDED CERAMIC PARTICLES,” filed Feb. 20, 2018, the entirety of which is incorporated herein by reference.

### TECHNICAL FIELD

The present description relates generally to glass-based articles for devices, and, more particularly, to surface glass with embedded ceramic particles.

### BACKGROUND

Some portable electronic devices contain glass, either internal or external. Externally, a glass article can be provided as part of a housing. Such a glass article is often referred to as a cover glass. A glass article can be provided to define an external surface and/or to support display technology. Glass can provide desirable aesthetic features to an electronic device when provided as an external surface. Additionally, an electronic device can provide a display technology layer beneath an outer cover glass. A sensing arrangement can also be provided with or adjacent to the display technology layer. By way of example, the display technology layer may include a liquid crystal display (“LCD”) that includes a liquid crystal module (“LCM”). The LCM generally includes an upper glass sheet and a lower glass sheet that sandwich a liquid crystal layer there between. The sensing arrangement may be a touch sensing arrangement such as those used to create a touch screen. For example, a capacitive sensing touch screen can include substantially transparent sensing points or nodes dispersed about a sheet of glass.

Unfortunately, however, heavy usage of such electronic devices can damage the glass. By defining an external surface of an electronic device, the glass can come into contact with other objects in a manner that tends to scratch the glass. Over time, such scratches can accumulate and diminish the appearance and function of the glass.

### BRIEF DESCRIPTION OF THE DRAWINGS

Certain features of the subject technology are set forth in the appended claims. However, for purpose of explanation, several embodiments of the subject technology are set forth in the following figures.

FIG. 1 shows a perspective view of an exemplary electronic device.

FIG. 2 shows a perspective exploded view of the electronic device of FIG. 1.

FIG. 3 shows a side view of a stage of an exemplary process for embedding ceramic particles within a glass body.

FIG. 4 shows a side view of a stage of an exemplary process for embedding ceramic particles within a glass body.

FIG. 5 shows a sectional view of an exemplary composite article.

FIG. 6 shows a sectional view of an exemplary composite article.

FIG. 7 shows a sectional view of an exemplary composite article.

FIG. 8 shows a sectional view of a stage of an exemplary process for embedding ceramic particles within a glass body.

FIG. 9 shows a sectional view of an exemplary composite article.

FIG. 10 shows a sectional view of an exemplary composite article.

FIG. 11 shows a sectional view of a stage of an exemplary process for forming an outer layer of a composite article.

FIG. 12 shows a sectional view of the outer layer of FIG. 11.

FIG. 13 shows a sectional view of the outer layer of FIG. 12 with a base layer.

FIG. 14 shows a sectional view of the integrated outer layer and base layer of FIG. 13.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and may be practiced without these specific details. In some instances, well-known structures and components are shown in block diagram form in order to avoid obscuring the concepts of the subject technology.

Glass articles can be used to provide optical, aesthetic, and/or tactile features that can be desired on an external surface of a product, such as a consumer electronic device. Such features have previously been achieved by preparing glass with a treatment that results in the desired appearance. For example, glass can be treated with dyes to provide a desired color and transparency. By further example, a glass article can receive a surface treatment, such as chemical etching or abrasive blasting, to achieve desired optical and tactile properties.

However, these treatments introduce flaws into the glass article and still leave a desire to provide the glass article with greater strength against damage and wear. Where a glass article defines an external surface of a device, heavy usage can damage the surface of the glass. The glass may then be susceptible to scratches and other damage, and the appearance and function of the glass can diminish over time.

Embodiments of the present disclosure provide a composite article that includes glass and provides desired optical, aesthetic, and/or tactile features, as well as enhanced strength against surface damage. By incorporating ceramic particles into the glass body of a composite article, a desired appearance can be achieved, along with greater strength provided by the presence of the ceramic particles at the surface of the glass body.

According to some embodiments of the present disclosure, the composite article can be an outer surface of an electronic device. The composite article can, for example, correspond to a glass cover that helps form part of a rear surface or a display area of an electronic device. Alternatively or additionally, the composite article may form a part of the housing.

These and other embodiments are discussed below with reference to FIGS. 1-14. However, those skilled in the art will readily appreciate that the detailed description given herein with respect to these figures is for explanatory purposes only and should not be construed as limiting.

Referring to FIG. 1, an electronic device 1 can be a portable or handheld electronic device having a thin form factor. The electronic device 1 can, for example, correspond to a portable media player, a media storage device, a portable digital assistant (“PDA”), a tablet, a computer, a mobile communication device (e.g., cellular phone or smart phone), a GPS unit, a remote control device, wristwatch, and the like. The electronic device 1 can be referred to as an electronic device or a consumer device.

The electronic device 1 can include a housing 8 that serves as an outer surface for the electronic device 1. Electrical components (not shown) are disposed within the housing 8. The electrical components can include a controller (or processor), memory, battery, and a display (e.g., LCD display). The electronic device 1 has one or more composite articles 10 provided at an external surface, e.g., front and/or rear surface, for the electronic device 1. The composite article 10 also resists scratching and therefore provides a substantially scratch-resistance surface for the electronic device 1. As further shown in FIG. 1, the composite article 10 can extend across the entire external surface of the housing 8. In such a case, the edges of the composite article 10 are aligned, or substantially aligned, with the sides of the housing 8. However, the composite article 10 can alternatively only be provided over a portion of a given surface of the housing 8.

Optionally, one or more glass-based composite articles 10 can be at least partially transparent so that the display area or other portion of the electronic device 1 can be viewed through the composite article 10. Such a display area can alternatively or additionally include a touch sensing device positioned over a display screen. For example, the display area can include one or more glass layers having capacitive sensing points distributed thereon.

Composite articles 10 can be continuous or include one or more openings to receive components of the electronic device 1 and/or provide access to an internal portion of the electronic device 1. For example, the electronic device 1 can include one or more audio speakers 4, and the composite article 10 can provide one or more openings 22 that provides a pathway for sound emitted from the speaker 4. By further example, the electronic device 1 can include one or more buttons 6, and the composite article 10 can provide one or more openings 24 for receiving the buttons 6. A variety of other openings can be provided for access or communication.

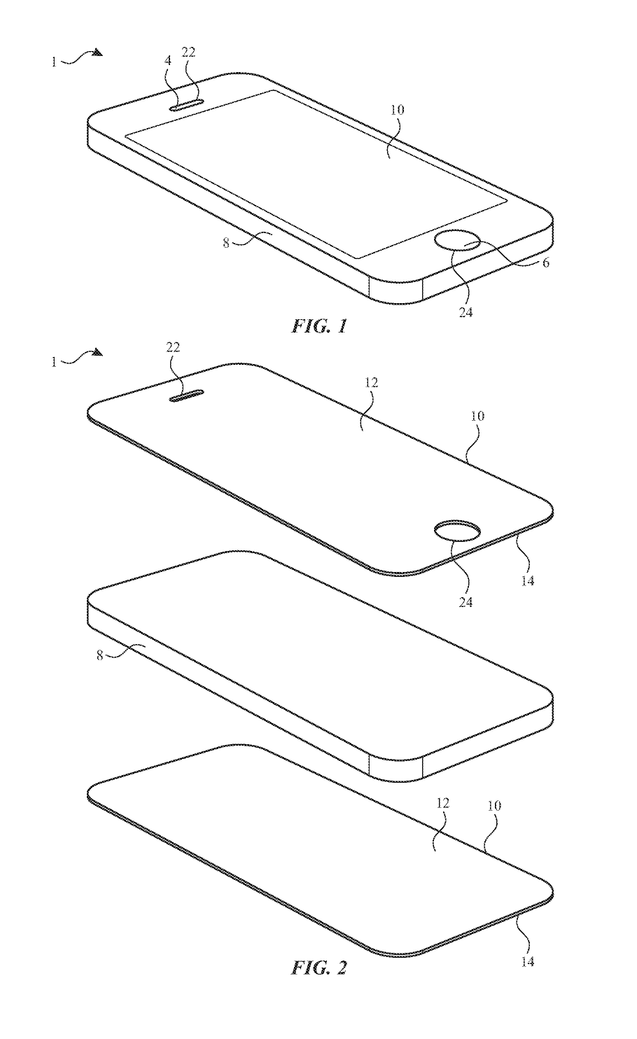

Referring to FIG. 2, each composite article 10 includes a thin sheet of glass. For example, the thickness of the glass in many applications is less or equal to 3 mm. The length, width, or area for the composite article 10 is dependent on the application. One application for a composite article 10 is as a cover glass for a housing of an electronic device, such as a portable or handheld electronic device. As illustrated in FIG. 2, each composite article 10 can include an outer surface 12 and an inner surface 14. Where applicable, the openings 22 and 24 can extend to the composite article 10, for example from the outer surface 12 to the inner surface 14.

It can be desirable for a composite article 10 to provide particular optical, aesthetic, and/or tactile features, as well as enhanced strength against surface damage. The methods and products described herein provide a variety of such features in various combinations by incorporating ceramic particles into the body of a composite article 10.

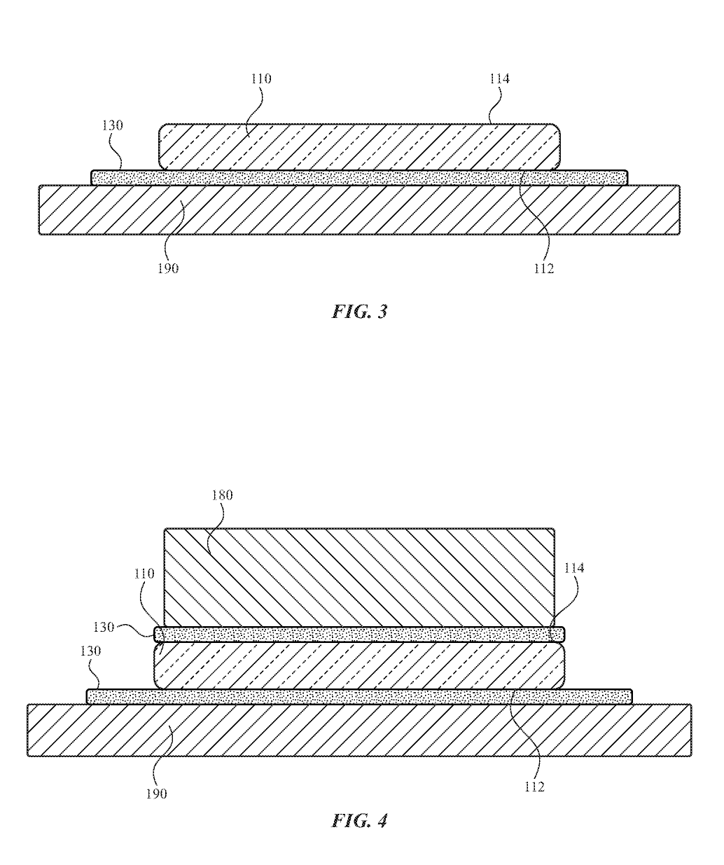

Referring to FIG. 3, a glass body 110 can be combined with ceramic particles 130 for embedding into the glass body 110 to form a composite article. The glass material for the glass body 110 can be selected from glass that has adequate strength. The glass body 110 can be formed into an appropriate size and shape, such as, for example, by singulating and/or machining.

A layer of ceramic particles 130, for example forming a powder, can be provided on a base plate 190, which is of a material that is resistant to a heating process. The ceramic particles 130 can optionally be fixed in place according to a desired arrangement. For example, the base plate 190 can include one or more troughs or patterns that allow for the ceramic particles 130 to be held in certain areas. Alternatively or in combination, the ceramic particles 130 can be applied with an adhesive or binder that keeps them in place. The adhesive or binder can subsequently burn away during heating, leaving only the ceramic particles 130. The glass body 110 can be positioned against the layer of ceramic particles 130. An outer surface 112 of the glass body 110 can be positioned against the ceramic particles 130, so that the ceramic particles 130 are embedded primarily into the outer surface 112. Optionally, the inner surface 114 may not receive any ceramic particles 130. The ceramic particles 130 can be positioned in a manner corresponding to the desired arrangement when embedded within the glass body 110, as discussed further herein. For example, the ceramic particles 130 can form a design, pattern, image, symbol, and/or text that is visually and/or tactilely recognizable by a user.

During a heating process, the glass body 110 is heated to a temperature that is sufficient to at least partially melt, anneal, and/or soften the glass body 110. For example, the glass body 110, the ceramic particles 130, and the base plate 190 can be provided within a furnace or other heating device or environment that provides the target temperature. The target temperature can be one that is sufficient to at least partially melt, anneal, and/or soften the glass body 110 without melting the ceramic particles 130 and the base plate 190. For example, the target temperature can be above a melting point of the glass body 110, but below melting points of the ceramic particles 130 and the base plate 190.

Materials for the glass body 110, the ceramic particles 130, and the base plate 190 can be selected accordingly. For example, alumina silicate glass is a suitable choice for the glass body 110. Other examples of glass materials include, but are not limited to, soda lime, borosilicate, and the like. The ceramic particles 130 can include silica, zirconia, alumina, and/or sapphire. Other suitable particles include materials that have a melting point higher than that of the glass body 110 and provide desirable hardness. The base plate 190 can be the same material as the ceramic particles 130 and/or a similar material.

When heated and under its own weight and/or an additional weight, the glass body 110 can flow into or otherwise absorb at least some of the ceramic particles 130 along the outer surface 112. The glass body 110 can be limited in its heat treatment, for example so that the main portion of the glass body 110 does not flow (i.e., outwardly to spread across the base plate 190). Rather, the portions of the glass body 110 at the outer surface 112 thereof can flow to fill interstitial spaces within the layer of the ceramic particles 130 and at least partially surround at least some of the ceramic particles 130. The ceramic particles 130 are then at least partially embedded into the glass body 110, and the glass body 110 can be cooled to securely capture the embedded ceramic particles 130.

Referring to FIG. 4, an embedding process can include elements in addition to the above-described process. For example, an additional layer of ceramic particles 130 can be provided against the inner surface 114 of the glass body 110, and a top plate 180 can be provided to press the additional layer of ceramic particles 130 into the inner surface 114 of the glass body 110. The top plate 180 can have properties similar to that of the base plate 190.

Referring to FIGS. 5-7, the composite article 100 resulting from one of the above-described processes can include both the glass body 110 and ceramic particles 130 embedded into the glass body 110. The ceramic particles 130 can define at least a portion of the outer surface 112 of the composite article 100. As such, the ceramic particles 130 can provide resistance to damage at the outer surface 112. The strength and/or hardness of the outer surface 112 can be defined by the properties of both the glass body 110 and the ceramic particles 130, as well as the distributions thereof. For example, the proportion of the outer surface 112 defined by the ceramic particles 130 enhances the average strength across the outer surface 112 as compared to the glass body 110 alone.

The depth of penetration for the ceramic particles 130 can be sufficient to provide the surface hardness. Whereas the ceramic particles 130 can be concentrated at the outer surface 112, a base layer 116 can have no ceramic particles 130. The base layer 116 can extend between the outer surface 112 and the inner surface 114, for example to the inner surface 114, and be considered a distinct layer of the glass body 110 or a separate glass body. The outer surface 112 can be an exposed surface. As such, the concentration of ceramic particles 130 at an outer layer (e.g., including the outer surface 112) can be greater than a concentration of ceramic particles 130 in the base layer 116. As used herein, “concentration” refers to the volumetric proportion (i.e., percentage) of the ceramic particles within the glass body.

As shown in FIG. 5, the ceramic particles 130 can be fully or partially embedded. For example, at least some of the ceramic particles 130 can protrude from the glass body 110, such that the outer surface 112 of the composite article 100 is uneven. This uneven surface provides a texture that can be felt tactilely by a user. Additionally, the uneven surface can scatter reflected light to provide a distinct appearance to a user. The ceramic particles 130 can be selected with one or more particle sizes, shapes, concentrations, colors, and/or distributions thereof to provide the desired look and feel. The ceramic particles 130 can have a size in a range from 1-100 μm. For example, the ceramic particles 130 can have a size that is about 1 μm, 10 μm, 20 μm, 30 μm, 40 μm, 50 μm, 60 μm, 70 μm, 80 μm, 90 μm, or 100 μm. For example, the size, shape and concentration can be selected for a particular texture. By further example, the size, shape, color, and concentration can be selected for a particular appearance. By further example, the size, shape, and concentration can be selected for a particular opacity, based on a desired degree of light transmission through the ceramic particles 130. Additionally or alternatively, at least some of the ceramic particles 130 can be transparent to provide enhanced strength at the outer surface 112 without reducing visibility through the composite article 100.

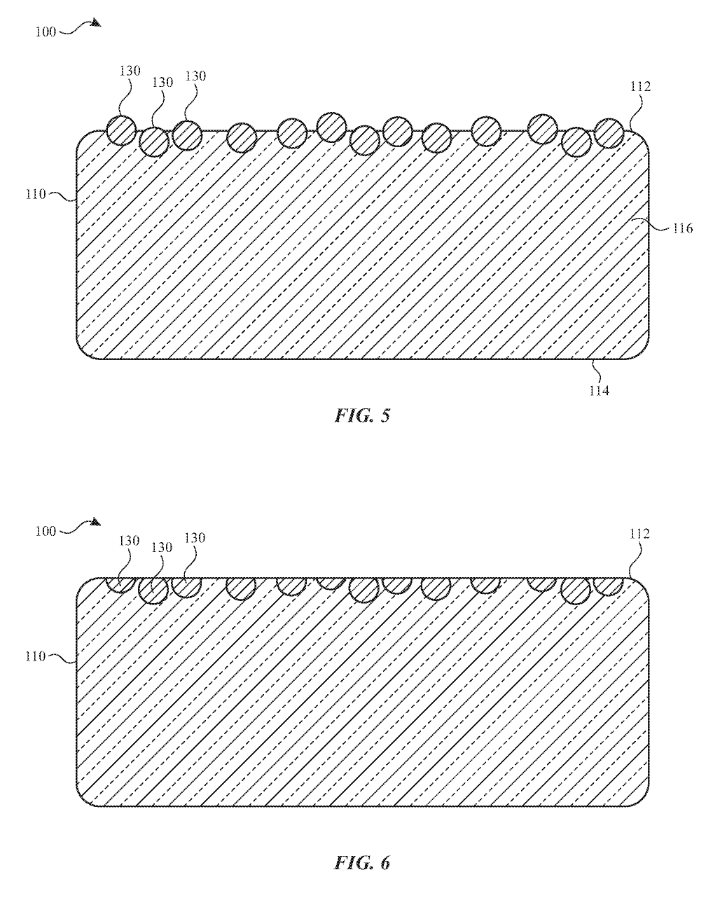

As shown in FIG. 6, the outer surface 112 of the composite article 100 can be treated to alter properties thereof. As shown, the outer surface 112 can be polished to reduce or eliminate protrusion of the ceramic particles 130 from the glass body 110. The polishing can be limited to the ceramic particles 130 or impact both the ceramic particles 130 and the glass body 110. The resulting outer surface 112 is generally more even and flat. This flat surface provides a texture that can be felt tactilely by a user. Additionally, the flat surface can reflect light with less scattering to provide a distinct appearance to a user. It will be appreciated that the polishing can be performed in select regions so that some regions of the outer surface 112 are uneven and other regions of the outer surface 112 are flat.

As shown in FIG. 7, the ceramic particles can be provided in a variety of configurations to produce desired features. For example, a first region of the outer surface 112 can include first ceramic particles 132, a second region of the outer surface 112 can include second ceramic particles 134, a third region of the outer surface 112 can include third ceramic particles 136, a fourth region of the outer surface 112 can include fourth ceramic particles 138, and one or more other regions of the outer surface 112 can include no ceramic particles.

One or more of the ceramic particles 132, 134, 136, and 138 can vary in particle sizes, shapes, concentrations, colors, and/or distributions thereof. The ceramic particles can be provided in a manner that forms a desired appearance. For example, different ceramic particles can be provided with different colors in different regions. By further example, different concentrations of ceramic particles can be provided in different regions to form different transparency or opacity features along the different regions. The ceramic particles can be provided in a manner that defines desired tactile properties. For example, different sizes and shapes of the ceramic particles can be provided in different regions to form different surface features along the different regions.

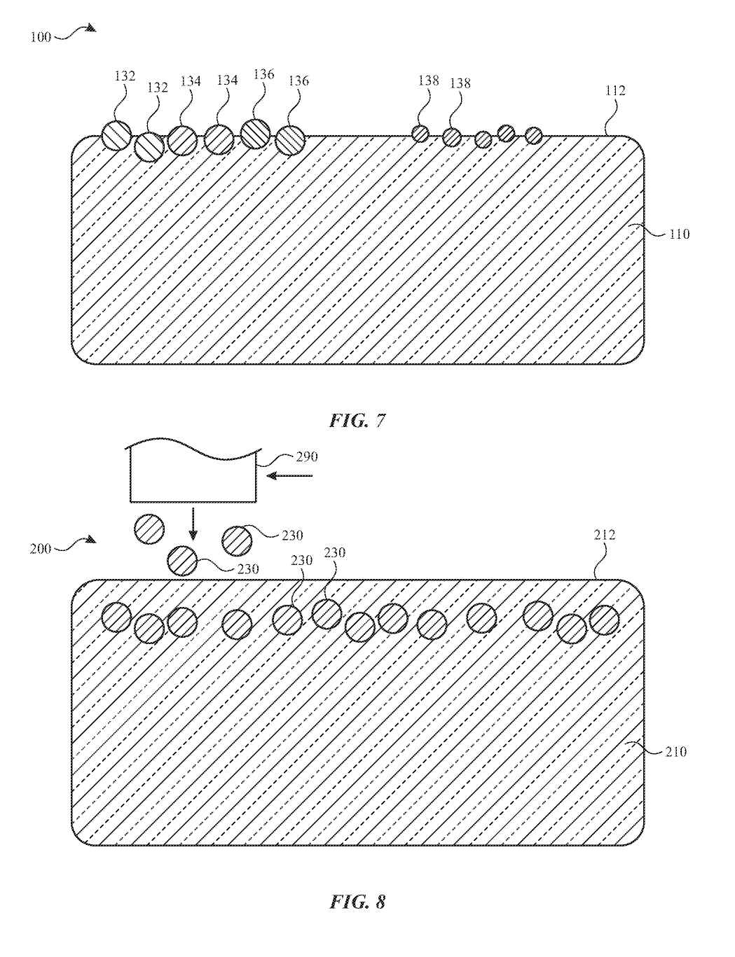

Referring to FIGS. 8-10, another process is depicted for embedding ceramic particles 230 in a glass body 210 to form a composite article. The glass body 210 and the ceramic particles 230 can be the same as or similar to the glass body 110 and the ceramic particles 130 discussed above. The process described below can provide the ceramic particles 230 with a greater depth of penetration, providing an ability to achieve particular surface features.

As shown in FIG. 8, ceramic particles 230 can be injected into the glass body 210 with momentum upon impact for penetrating the outer surface 212. During a heating process, the glass body 210 is heated to a temperature that is sufficient to at least partially melt, anneal, and/or soften the glass body 210. For example, the glass body 210 can be provided within a furnace or other heating device or environment that provides the target temperatures. The target temperature can be above a melting point of the glass body 210, but below melting points of the ceramic particles 230. A jet device 290 can direct the ceramic particles 230 as projectiles toward the glass body 210, which penetrate the outer surface 212 based on the momentum of the ceramic particles 230. The jet device 290 can move over the outer surface 212 to provide the ceramic particles 230 in a desired arrangement. The characteristics of the ceramic particles 230 can vary across different regions by changing the feed of ceramic particles as the jet device 290 moves. For example, the particle sizes, shapes, concentrations, colors, and/or distributions can vary during the process by changing feeds and/or altering operation of the jet device 290 (e.g., rate of providing particles, speed of movement, etc.). The glass body 210 can be cooled to securely capture the embedded ceramic particles 230 and form the composite article 200.

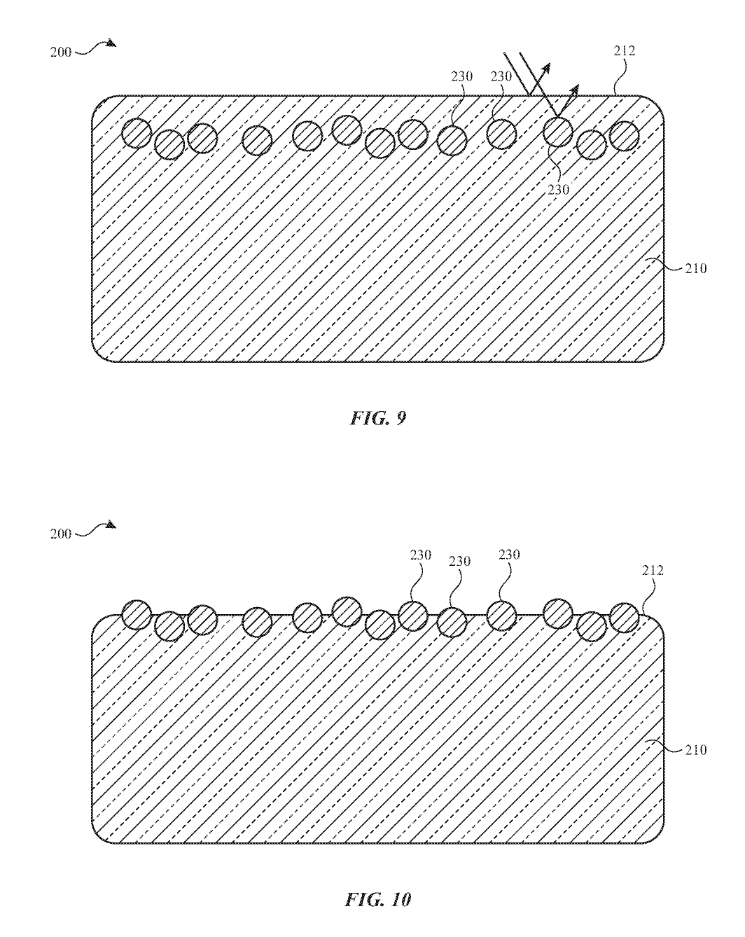

As shown in FIG. 9, the ceramic particles 230 can be fully embedded or immersed within the glass body 210 of the composite article 200. As such, the outer surface 212 can be entirely defined by the glass body 210, rather than by any ceramic particles 230 protruding. The resulting outer surface 212 can be smooth (e.g., flat) and reflective for at least some of the incident light. Furthermore, the ceramic particles 230 can provide visual features by reflecting and scattering at least some of the light that penetrates the outer surface 212. As a result, the composite article 200 can have a degree of opacity that provides a hazy appearance while maintaining a smooth outer surface 212. Conventional techniques for achieved a hazy appearance include surface treatments, such as chemical etching or abrasive blasting. However, these surface treatments yield an uneven, rough surface. It can be desirable to provide such visual features while maintaining a smooth surface, as provided by the above process.

As shown in FIG. 10, the composite article 200 can be subject to an optional surface treatment. For example, select regions of the outer surface 212 can be treated to provide a smooth outer surface 212 in some regions and an uneven, rough outer surface 212 in other regions. Such treatments include chemical etching to remove a portion of the glass body 210, for example with hydrofluoric acid or another etchant. Chemical etching can remove portions of the glass body 210 while leaving the ceramic particles 230 substantially unchanged. Other treatments include abrasive blasting and/or polishing (see FIG. 6), which may manipulate both the glass body 210 and the ceramic particles 230.

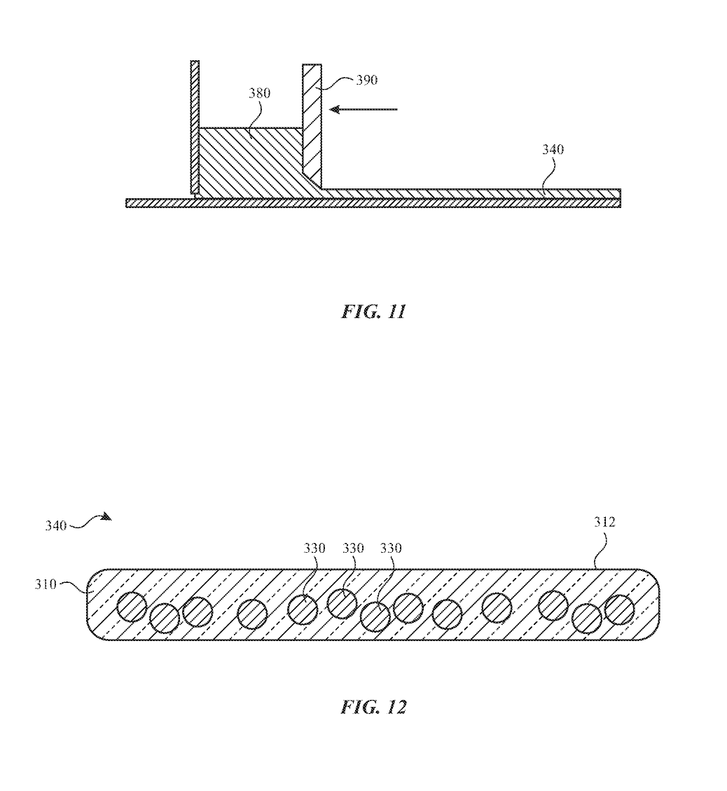

Referring to FIGS. 11-14, separate layers of a composite article can be formed separately and the combined to produce the final product. As shown in FIG. 11, the outer layer 340 can be formed as a mixture of glass and ceramic particles produced by a mixing device 390. FIG. 11 depicts an exemplary tape casting process, in which a slurry 380 of the glass and ceramic particles are applied as a thin sheet, for example with a doctor blade of a mixing device 390. The process can be performed at a target temperature at which the glass can flow. For example, the target temperature can be above a melting point of the glass, but below melting points of the ceramic particles. The characteristics of the ceramic particles can vary across different regions by changing the feed of the slurry 380. For example, the particle sizes, shapes, concentrations, colors, and/or distributions can vary during the process by changing feeds and/or altering operation of the mixing device 390. The sheet can be cooled to securely capture the embedded ceramic particles and form the outer layer 340.

As shown in FIG. 12, the ceramic particles 330 can be fully embedded or immersed within the glass body 310 of the outer layer 340. As such, the outer surface 312 can be entirely defined by the glass body 310, rather than by any ceramic particles 330 protruding. The resulting outer surface 312 can be smooth (e.g., flat) and reflective for at least some of the incident light. Furthermore, the ceramic particles 330 can provide visual features by reflecting and scattering at least some of the light that penetrates the outer surface 312. As a result, the composite article 300 can have a degree of opacity that provides a hazy appearance while maintaining a smooth outer surface 312.

The properties of the resulting outer layer 340 can be controlled based on the operation of the tape casting device. For example, the tape casting device can be operated to form an outer layer 340 of a desired thickness. The thickness of the outer layer 340 can, at least in part, determine the opacity and other optical properties of the outer layer 340. For example, a thicker outer layer 340 of a given concentration of ceramic particles 330 within the glass body 310 provides a lower transmission of light there through. Accordingly, various optical properties of the final product can be determined by controlling production parameters of the outer layer 340. The thickness of the outer layer 340 can be about 100 μm, for example, 50 μm, 60 μm, 70 μm, 80 μm, 90 μm, 100 μm, 110 μm, 120 μm, 130 μm, 140 μm, or 150 μm.

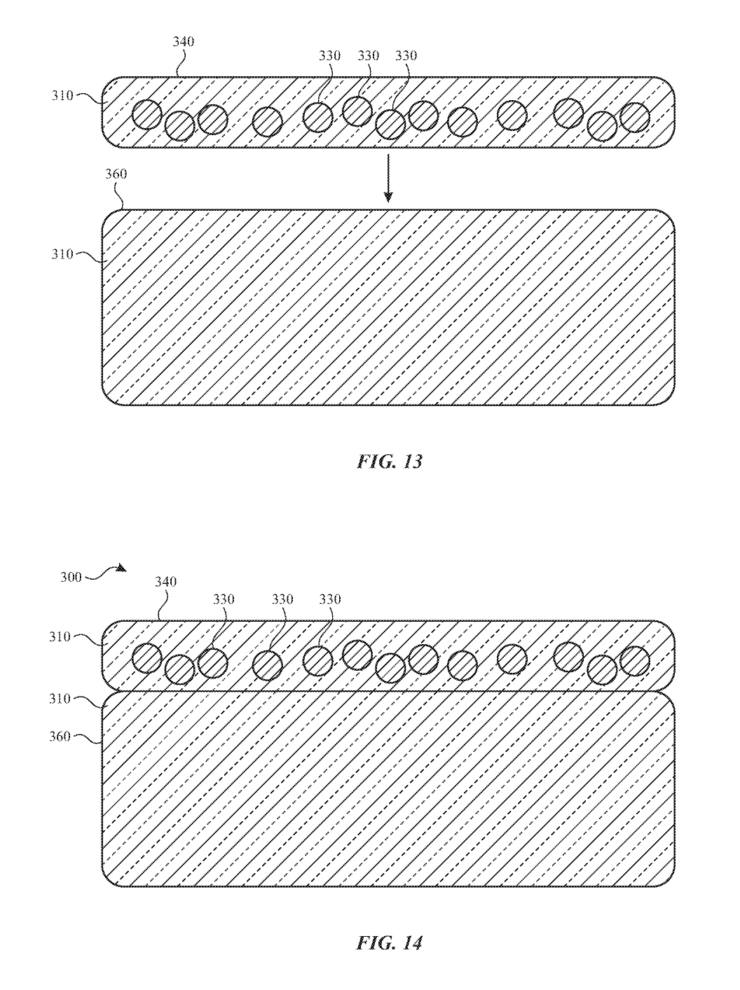

As shown in FIGS. 13 and 14, the outer layer 340 can be combined with a base layer 360. The base layer 360 can include a glass body 310 that is the same as or similar to the glass body 310 of the outer layer 340. For example, each glass body 310 can be of the same glass material. However, the base layer 360 can include fewer or no embedded ceramic particles 330.

The outer layer 340 and the base layer 360 can be combined during a heating process in which each glass body 310 is heated to a temperature that is sufficient to at least partially melt, anneal, and/or soften each glass body 310. For example, the outer layer 340 and the base layer 360 can be provided within a furnace or other heating device or environment that provides the target temperature. The target temperature can be one that is sufficient to at least partially melt, anneal, and/or soften each glass body 310 without melting the ceramic particles 330. For example, the target temperature can be above a melting point of each glass body 310, but below melting points of the ceramic particles 330. The resulting composite article 300 can have a unitary, integral, and monolithic glass body 310 spanning the outer layer 340, with ceramic particles 330, and the base layer 360, having fewer or no ceramic particles 330.

Optionally, the composite article 300 can be subject to a surface treatment. For example, select regions of the outer surface 312 can be treated to provide a smooth outer surface 312 in some regions and an uneven, rough outer surface 312 in other regions. Such treatments include those discussed above with respect to FIG. 10.

A reference to an element in the singular is not intended to mean one and only one unless specifically so stated, but rather one or more. For example, “a” module may refer to one or more modules. An element proceeded by “a,” “an,” “the,” or “said” does not, without further constraints, preclude the existence of additional same elements.

Headings and subheadings, if any, are used for convenience only and do not limit the invention. The word exemplary is used to mean serving as an example or illustration. To the extent that the term include, have, or the like is used, such term is intended to be inclusive in a manner similar to the term comprise as comprise is interpreted when employed as a transitional word in a claim. Relational terms such as first and second and the like may be used to distinguish one entity or action from another without necessarily requiring or implying any actual such relationship or order between such entities or actions.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A phrase “at least one of” preceding a series of items, with the terms “and” or “or” to separate any of the items, modifies the list as a whole, rather than each member of the list. The phrase “at least one of” does not require selection of at least one item; rather, the phrase allows a meaning that includes at least one of any one of the items, and/or at least one of any combination of the items, and/or at least one of each of the items. By way of example, each of the phrases “at least one of A, B, and C” or “at least one of A, B, or C” refers to only A, only B, or only C; any combination of A, B, and C; and/or at least one of each of A, B, and C.

It is understood that the specific order or hierarchy of steps, operations, or processes disclosed is an illustration of exemplary approaches. Unless explicitly stated otherwise, it is understood that the specific order or hierarchy of steps, operations, or processes may be performed in different order. Some of the steps, operations, or processes may be performed simultaneously. The accompanying method claims, if any, present elements of the various steps, operations or processes in a sample order, and are not meant to be limited to the specific order or hierarchy presented. These may be performed in serial, linearly, in parallel or in different order. It should be understood that the described instructions, operations, and systems can generally be integrated together in a single software/hardware product or packaged into multiple software/hardware products.

In one aspect, a term coupled or the like may refer to being directly coupled. In another aspect, a term coupled or the like may refer to being indirectly coupled.

Terms such as top, bottom, front, rear, side, horizontal, vertical, and the like refer to an arbitrary frame of reference, rather than to the ordinary gravitational frame of reference. Thus, such a term may extend upwardly, downwardly, diagonally, or horizontally in a gravitational frame of reference.

The disclosure is provided to enable any person skilled in the art to practice the various aspects described herein. In some instances, well-known structures and components are shown in block diagram form in order to avoid obscuring the concepts of the subject technology. The disclosure provides various examples of the subject technology, and the subject technology is not limited to these examples. Various modifications to these aspects will be readily apparent to those skilled in the art, and the principles described herein may be applied to other aspects.

All structural and functional equivalents to the elements of the various aspects described throughout the disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for”.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the claims. In addition, in the detailed description, it can be seen that the description provides illustrative examples and the various features are grouped together in various implementations for the purpose of streamlining the disclosure. The method of disclosure is not to be interpreted as reflecting an intention that the claimed subject matter requires more features than are expressly recited in each claim. Rather, as the claims reflect, inventive subject matter lies in less than all features of a single disclosed configuration or operation. The claims are hereby incorporated into the detailed description, with each claim standing on its own as a separately claimed subject matter.

The claims are not intended to be limited to the aspects described herein, but are to be accorded the full scope consistent with the language claims and to encompass all legal equivalents. Notwithstanding, none of the claims are intended to embrace subject matter that fails to satisfy the requirements of the applicable patent law, nor should they be interpreted in such a way.

What is claimed is:

1. An electronic device comprising:
a housing; and
a composite article within the housing, the composite article comprising:
a glass body; and
ceramic particles embedded within the glass body and defining a portion of an outer surface of the composite article, wherein the outer surface forms a portion of an exterior surface of the electronic device.

2. The electronic device of claim 1, wherein the ceramic particles comprise:
first ceramic particles at a first region of the outer surface; and
second ceramic particles at a second region of the outer surface, wherein the first ceramic particles differ from the second ceramic particles in at least one of size, shape, color, or concentration.

3. The electronic device of claim 1, wherein the ceramic particles and the glass body both define the outer surface.

4. The electronic device of claim 1, further comprising a display for transmitting light through the composite article.

5. The electronic device of claim 1, wherein at least some of the ceramic particles extend outside the glass body.

6. A composite article comprising:
a first layer defining an outer surface of the composite article and comprising a first glass body and ceramic particles embedded within the first glass body; and
a second layer adjacent to the first layer and comprising a second glass body, wherein a concentration of ceramic particles in the second layer is lower than a concentration of the ceramic particles in the first layer.

7. The composite article of claim 6, wherein the ceramic particles comprise:
first ceramic particles within a first region of the first glass body; and
second ceramic particles within a second region of the first glass body, wherein the first ceramic particles differ from the second ceramic particles in at least one of size, shape, color, or concentration.

8. The composite article of claim 6, wherein the ceramic particles and the first glass body both define the outer surface.

9. The composite article of claim 6, wherein at least some of the ceramic particles extend outside the first glass body.

10. The composite article of claim 6, wherein the first glass body defines an entirety of the outer surface.

11. The composite article of claim 6, wherein each of the ceramic particles is immersed within the first glass body.

12. A method of forming a composite article, the method comprising:
embedding an outer layer of a glass body with ceramic particles wherein the composite article comprises the outer layer and a base layer, wherein the outer layer defines an outer surface of the composite article and a concentration of ceramic particles in the base layer is lower than a concentration of the ceramic particles in the outer layer.

13. The method of claim 12, wherein embedding comprises:
heating the glass body until the glass body flows around the ceramic particles, the ceramic particles being between the glass body and a plate;
cooling the glass body; and
removing the glass body from the plate.

14. The method of claim 12, wherein the ceramic particles comprise first ceramic particles and second ceramic particles and the embedding comprises:
heating the glass body until the glass body flows around the first ceramic particles and the second ceramic particles, the first ceramic particles being between the glass body and a first plate and the second ceramic particles being between the glass body and a second plate;
cooling the glass body; and
removing the glass body from the first plate and the second plate.

15. The method of claim 12, wherein embedding comprises:
heating the glass body;
directing the ceramic particles with momentum to penetrate the outer layer; and
cooling the glass body.

16. The method of claim 12, wherein:
the glass body is a first glass body;
embedding comprises:
forming the outer layer from a slurry comprising the ceramic particles and a glass material; and
joining the outer layer of the first glass body to the base layer of a second glass body.

17. The method of claim 12, wherein the ceramic particles define a portion of the outer surface.

18. The method of claim 12, further comprising polishing the outer layer such that the ceramic particles are exposed at the outer surface.

19. The method of claim 12, further comprising removing a portion of the glass body from the outer surface.

20. The method of claim 12, further comprising securing the composite article within a housing of an electronic device.
